(19) United States
(12) Patent Application Publication
(10) Pub. No.: US 2011/0214714 A1
(43) Pub. Date: Sep. 8, 2011

(54) THIN-FILM SOLAR CELL INTERCONNECTION

(76) Inventors: Armin Gerhard Aberle, Singapore (SG); Per Ingemar Widenborg, Singapore (SG); Peter Jaroslav Gress, New South Wales (AU)

(21) Appl. No.: 12/999,160

(22) PCT Filed: Jun. 16, 2009
(86) PCT No.: PCT/SG2009/000213

§ 371 Date: May 24, 2011

(30) Foreign Application Priority Data
Jun. 17, 2008 (AU) 2008903093

(51) Int. Cl. H01L 31/048; H01L 31/18

(52) U.S. Cl. 136/251; 438/66; 257/E31.117

(57) ABSTRACT

A thin-film solar cell module, and a method of interconnecting two or more thin-film solar cells on a foreign supporting substrate. The method comprises the step of wire-bonding an air-side electrode of one thin-film solar cell to a substrate-side electrode of an adjacent solar cell, such that said thin-film solar cells are connected in series.

### FIELD OF INVENTION

The present invention relates broadly to a method of interconnecting two or more thin-film solar cells, and to a thin-film solar cell module.

### BACKGROUND

Thin-film solar cells on foreign supporting materials such as glass are receiving increasing attention. Thin-films have the potential to dramatically reduce the cost of manufacture of photovoltaic (PV) modules due to the fact that they only require a fraction of the semiconductor material as compared to traditional silicon wafer based modules. Thin-film solar cells, furthermore, have the advantage that it is possible to manufacture them on large-area supporting materials (˜1 m²), streamlining the production process and further reducing processing costs. To enable extraction of power from a solar cell, contacts need to be created to the negative and positive terminals of the device and conductive paths (usually made of metal) need to deliver the current and voltage out from the device. Hence, all solar cells have a metallization process that fabricates such contacts and conductive pathways. Due to the large size of thin-film PV modules, it is important to divide the large (˜1 m²) initial thin-film solar cell into smaller unit cells and then interconnect them in series to keep ohmic losses at a tolerable level.

Work on foreign supporting materials (mainly glass) in the 1970s and 1980s has established hydrogenated amorphous silicon (a-Si:H) deposited by PECVD (plasma-enhanced chemical vapour deposition) at about 200° C. as the baseline thin-film PV technology (see, for example: K. Kuwano, S. Tsuda, M. Onishi, H. Nishikawa, S. Nakano, and T. Imai, Japanese Journal of Applied Physics, 1980, vol. 20, p. 213). The technology possesses a number of excellent properties for low-cost PV electricity, including a high optical absorption coefficient of the semiconductor material (enabling very thin absorber layer thicknesses of 300 nm or less), large-area silicon diode deposition at low temperature (˜200° C.) onto rigid or flexible substrates, and monolithic series interconnection of the individual cells. The only reason why a-Si:H has not been able to conquer a significant share of the global PV market is the low stable average efficiency of 6% or less of large-area single-junction PV modules.

A typical way how adjacent a-Si:H solar cells are interconnected is shown in FIG. 1. The method is based on two fundamental requirements: (i) the supporting material 100 (glass) is electrically non-conductive; (ii) each of the individual layers (p⁺, i, n⁺) of the solar cells 102 has very high sheet resistance (>10⁵ Ω/square), ensuring that the solar cells 102 are negligibly shunted when the rear TCO (transparent conductive oxide) layer 106 is deposited over the exposed sidewall region of each cell. The solar cell process starts with the deposition of the front or glass-side TCO layer 108, followed by the first set of parallel scribes (“scribe 1”) that defines the individual solar cells. Then the three semiconductor layers forming the solar cells 102 are deposited. The next step is the second set of parallel scribes (“scribe 2”) which cuts through the deposited semiconductor layers and thereby locally exposes the buried TCO layer 108. Then follows the blanket deposition of the rear electrode (rear TCO 106 plus metal 110). Finally, the third set of parallel scribes (“scribe 3”) cuts through the rear electrode (metal 110 and TCO 106) and the semiconductor layers, eliminating the shunting path for the current flow and leading to the series connection of all solar cells 102 on the glass pane 100.

If the heavily doped layers of the solar cell have good lateral conductance (i.e., sheet resistances of well below 10⁴ Ohm/square), the scheme of FIG. 1 is not applicable because all solar cells 102 would be severely shunted by the TCO layer 106 deposited onto the exposed sidewall regions of the cells 102. Polycrystalline silicon is a semiconductor material that falls into this category. One method for forming a series-connected thin-film PV module based on polycrystalline silicon has been disclosed by Basore [P. A. Basore, Simplified processing and improved efficiency of crystalline silicon on glass modules, Proc. 19th European Photovoltaic Solar Energy Conference, Paris, 2004, p. 455 (WIP, Munich, 2004)]. The technology is referred to as CSG (for Crystalline Silicon on Glass). To achieve light trapping, both surfaces of a borosilicate glass superstrate are textured with a dip coating process that leaves a monolayer of silica beads embedded in a sol-gel matrix. A silicon nitride antireflection coating is deposited onto one surface, followed by deposition using PECVD at 45 nm/min of a-Si having an n⁺pp⁺ structure. The Si-coated glass sheets are heated to 600° C. in a batch oven for several hours to achieve solid-phase crystallisation. Crystallographic defects are annealed by heating the c-Si briefly (˜1 min) to over 900° C., using a rapid thermal anneal (RTA) process. Most of the remaining defects are passivated by exposure to atomic hydrogen. Device fabrication starts by using a pulsed laser to slice the Si layer into a series of adjacent, ˜6 mm wide strip cells. The module is then coated with a thin layer of Novolac resin loaded with white pigments to make it more reflective and thus improve light trapping in the cell. Next the openings for the n-type contacts (“craters”) are formed. This involves etching of openings into the resin layer (using an ink-jet printhead), followed by chemical etching of the Si. Then the openings for the p-type contacts (“dimples”) are formed using the same ink-jet process. A blanket deposition of sputtered aluminium provides electrical contact to the n⁺ and p⁺ Si layers. The aluminium film is then sliced into a large number of individual pads using laser pulses. Each metal pad series connects one line of p-type contacts in one cell with a line of n-type contacts in the next cell. It is noted that this metallization and interconnection scheme does not involve a TCO layer.

One potential problem with the Basore technique recognised by the inventors is the large number of craters and dimples that need to be created. For example, for a solar module of 1 m² area, millions of craters and dimples need to be formed. Another problem recognised by the inventors is that all craters and dimples need to be accurately positioned across the entire module, imposing significant challenges with respect to the alignment of the glass sheet and the patterning tools (such as inkjet, laser). Embodiments of the present invention seek to address at least one of those problems.

### SUMMARY

In accordance with a first aspect of the present invention there is provided a method of interconnecting two or more thin-film solar cells on a foreign supporting substrate, the method comprising the step of wire-bonding an air-side electrode of one thin-film solar cell to a substrate-side electrode of an adjacent solar cell, such that said thin-film solar cells are connected in series.

The wire-bonding may comprise using one or more of a group consisting of a round wire, a flattened wire, and a ribbon.

The air-side electrode may comprise an air-side busbar and a plurality of air-side finger electrodes connected to the air-side busbar, and the substrate-side electrode may comprise a substrate-side busbar and a plurality of substrate-side finger electrodes connected to the substrate-side busbar.

The method may comprise wire-bonding the air-side busbar of said one solar cell to the substrate-side busbar of said adjacent solar cell.

The method may further comprise wire-bonding the substrate-side electrode of a first one of the series connected thin-film solar cells to a first external busbar, and wire-bonding the air-side electrode of a last one of the series connected thin-film solar cells to a second external busbar.

The method may further comprise providing respective conductive tapes on a first one and a last one of the series of connected thin-film solar cells such that the conductive tapes are electrically insulated from surfaces of the first one and a last one of the series of connected thin-film solar cells, and wire-bonding the substrate-side electrode of the first one of the series connected thin-film solar cells and the air-side electrode of the last one of the series connected thin-film solar cells to the respective conductive tapes.

The conductive tapes may be adhered to the first one and the last one of the series connected thin-film solar cells via respective non-conductive adhesives.

The method may further comprise encapsulating the wire-bonding formed connections.

An entire air-side surface of the series connected thin-film solar cells may be encapsulated.

In accordance with a second aspect of the present invention there is provided thin-film solar cell module comprising two or more thin-film solar cells; and a wire-bonding-formed electrical connection between an air-side electrode of one thin-film solar cell to a substrate-side electrode of an adjacent solar cell, such that said thin-film solar cells are connected in series.

The wire-bonding-formed connection may comprise one or more of a group consisting of a round wire, a flattened wire, and a ribbon.

The air-side electrode may comprise an air-side busbar and a plurality of air-side finger electrodes connected to the air-side busbar, and the substrate-side electrode may comprise a substrate-side busbar and a plurality of substrate-side finger electrodes connected to the substrate-side busbar.

The wire-bonding-formed connection may be between the air-side busbar of said one solar cell to the substrate-side busbar of said adjacent solar cell.

The substrate-side busbar may accommodate respective pad areas for the wire-bonding-formed connection.

One or more of the substrate-side electrodes may comprise a widened pad portion for accommodating respective pad areas for the wire-bonding-formed connection.

The solar cell module may further comprise a wire-bonding-formed connection between the substrate-side electrode of a first one of the series connected thin-film solar cells to a first external busbar of the solar cell module, and a wire-bonding-formed connection between the air-side electrode of a last one of the series connected thin-film solar cells to a second external busbar of the solar cell module.

The solar cell module may further comprise respective conductive tapes on a first one and a last one of the series of connected thin-film solar cells such that the conductive tapes are electrically insulated from surfaces of the first one and a last one of the series of connected thin-film solar cells, and wire-bonding formed connections of the substrate-side electrode of the first one of the series connected thin-film solar cells and the air-side electrode of the last one of the series connected thin-film solar cells to the respective conductive tapes.

The conductive tapes may be adhered to the first one and the last one of the series connected thin-film solar cells via respective non conductive adhesives.

The solar cell module may further comprise an encapsulation for the wire-bonding formed connections.

An entire air-side surface of the series connected thin-film solar cells may be encapsulated.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 shows a schematic cross-sectional drawing illustrating a prior art way how adjacent a-Si:H solar cells are interconnected.

FIG. 2 shows a schematic air-side top view of a mini-module using wire-bonded cell interconnects according to an example embodiment.

FIG. 3 is a graph showing the fractional power loss as a function of the number of wire bonds in example embodiments.

FIG. 4 shows a schematic air-side top view of a mini-module using wire-bonded cell interconnects with external leads attached according to an example embodiment.

FIGS. 5a to 5j show schematic cross-sectional views illustrating a manufacturing technique for fabricating an interdigitated poly-Si thin-film solar cell according to an example embodiment.

FIG. 6 shows a top (air-side) view of the structure after the step shown in FIG. 5j.

FIG. 7 shows a plot of current-voltage (I-V) curves measured for three individual solar cells (A, B and C), and the resulting mini-module after interconnection using wire-bonding according to an example embodiment.

FIG. 8 shows a schematic air-side top view of a sample mini-module according to an example embodiment.

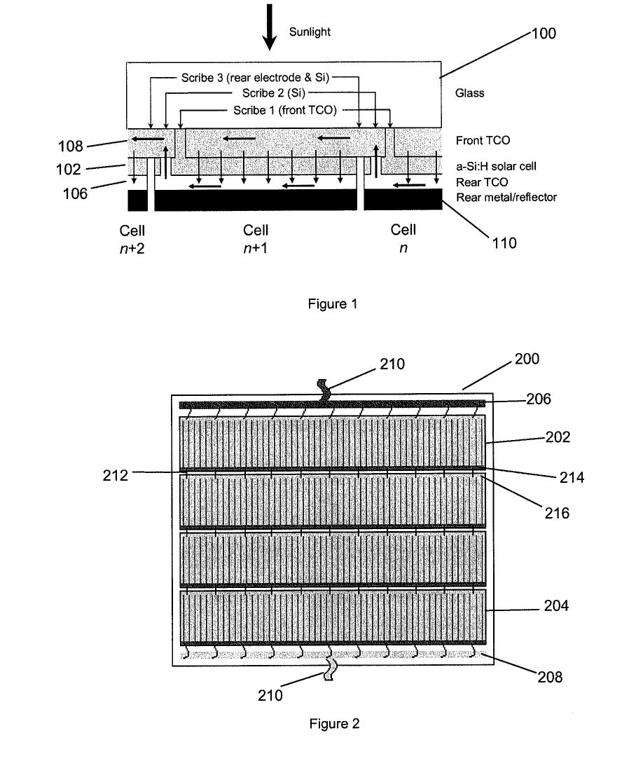

### DETAILED DESCRIPTION

Example embodiments of the present invention provide a method of manufacture of thin-film photovoltaic (PV) modules. In particular, the described example embodiments provide a method of interconnecting individual interdigitated thin-film solar cells on a foreign supporting substrate using wire-bonding or associated methods such as ribbon-bonding, followed by encapsulation of the wire- or ribbon-bonded thin-film solar cells by spray coating with a durable material.

An air-side top view of a mini-module 200 using wire-bonded cell interconnects is schematically shown in FIG. 2. Wire bonding is also used to connect the first 202 and last 204 solar cell in the string to large external busbars 206, 208. These external busbars 206, 208 are used for attaching (for example by soldering) thick metal leads 210 to the PV module 200 for harnessing a photovoltaic output from the PV module 200.

In FIG. 2, a 4-cell interdigitated mini-module with 11 wire-bonds e.g. 212 (black lines) per busbar pair 214, 216 is shown. It is noted that the cell features are not to scale and the black wire-bond lines are considerably visually thicker than would be the case for an actual PV module.

PV modules manufactured according this example embodiment undergo the steps of:
p-n junction formation.
Metallisation on cell level using two interdigitated comb-like electrodes.
Cell isolation using laser scribes.
Cell interconnection using wire-bonding.
A durable coating (for example white epoxy), which functions as an environmental protection layer, is applied to the surface of the wire bonds.

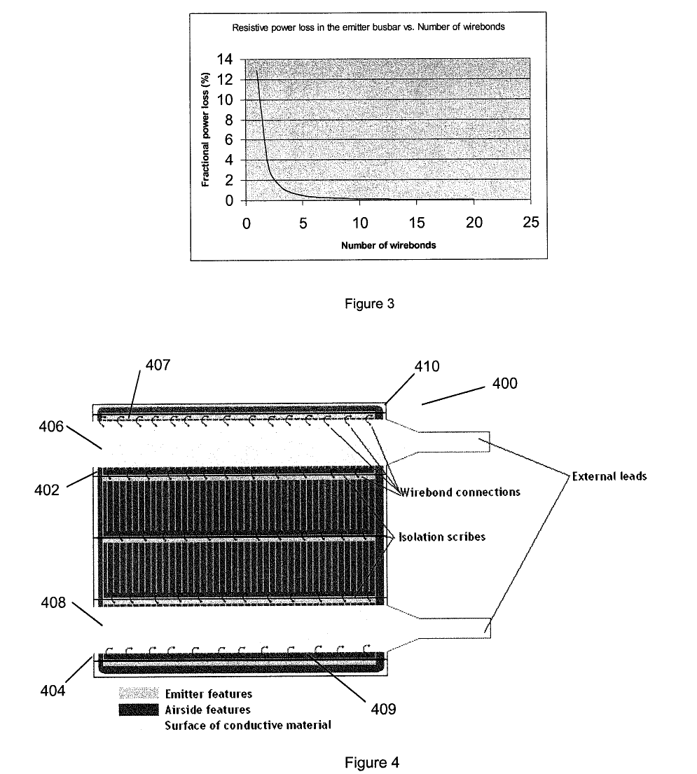

In one example, a wire-bonding technology with a 150-μm² area for a complete ultrasonic wire-bond, and a row of four interdigitated solar cells each with area 4 cm×1 cm are considered. The emitter busbar 214 of each cell is 150 μm wide to accommodate the pad area for the wire bonding, and 4 cm long, resulting in a fractional shadow loss of 1.5%. The maximum amount of wire-bonds that can be placed on the busbar is 4 cm/150 μm=266. Placing this amount of wire-bonds on a busbar may be unrealistic under most circumstances. In the following, the effect of having a lower amount of wire-bonds across the busbar is considered. The fractional power loss across a uniform emitter busbar of width equal to W_{wb} is

$${P}_{L} = \frac{1}{3} {A}^{2} B {ρ}_{s} {U}_{MP} \frac{1}{{W}_{wb}} \qquad ( 1 )$$

where A is half the distance between wire-bonds connections (A=C/2x, where x is the number of wire-bonds and C is the cell length). Assuming interdigitated solar cells with the following parameters: Emitter busbar shape=uniform, total cell length C=4.0 cm, total cell width B=1.0 cm, busbar sheet resistivity ρₛ=0.0264 Ω/sqr, U_{MP}=J_{MP}/V_{MP}=0.05 Ω⁻¹ cm⁻², W_{wb}=150 μm. For this case, the fractional power loss as a function of the number of wire bonds is shown in FIG. 3. It can be seen that even at 14 wire-bonds evenly distributed across 4 cm (around 5% of the physical maximum), the fractional resistive power loss in the emitter busbar is almost negligible. This demonstrates that a relatively low density of wire bonds is suitable in actual PV modules to ensure the emitter busbar losses are at negligible levels.

An air-side top view of a mini-module 400 using wire-bonded cell interconnects according to another embodiment is schematically shown in FIG. 4. Wire bonding is also used to connect the first 402 and last 404 solar cell in the string to respective conductive tapes 406, 408.

PV modules manufactured according to this example embodiment undergo the steps of:
p-n junction formation.
Metallisation on cell level using two interdigitated comb-like electrodes.
Cell isolation using laser scribes.
Tape with a conductive top surface and insulating bottom surface is attached to the respective opposing end cells.
Cell interconnection using wire-bonding.
A durable coating (for example white epoxy), which functions as an environmental protection layer, is applied to the surface of the wire bonds.

In this example embodiment the conductive tape e.g. 406 is placed with a non-conductive adhesive (hidden) over the metallised surface of the thin-film solar cell e.g. 402 which has been deposited on the glass substrate 410. The conductive tapes 406, 408 are then connected to the substrate-side and air-side busbar 407, 409 respectively of the first and last cells 402, 404 via wire-bonding as a replacement to soldering, such that the desired interconnection layout is achieved. The tapes 406, 408 thus function as external leads.

In this example embodiment the busbar features can be reduced in area, as the busbars are no longer the main transport mechanism for current to and from the module 400.

This can provide the additional advantage of reducing the resistive losses from the module 400 to an external load (not shown), as the tape can usually be thicker (e.g. about 30-50 microns) compared to a typical cell busbar thickness (e.g. about 0.6-2 microns).

The fact that the conductive tapes 406, 408 each cover a larger area—almost the entire area of the rear surface of one cell—can also result in a reduction of electrical resistance to an external load (not shown).

Additional benefits of this example embodiment can include an increased current density, as the area occupied by the large external busbars 206, 208 in the embodiment shown in FIG. 2 may now contain active silicon material for the absorption of light.

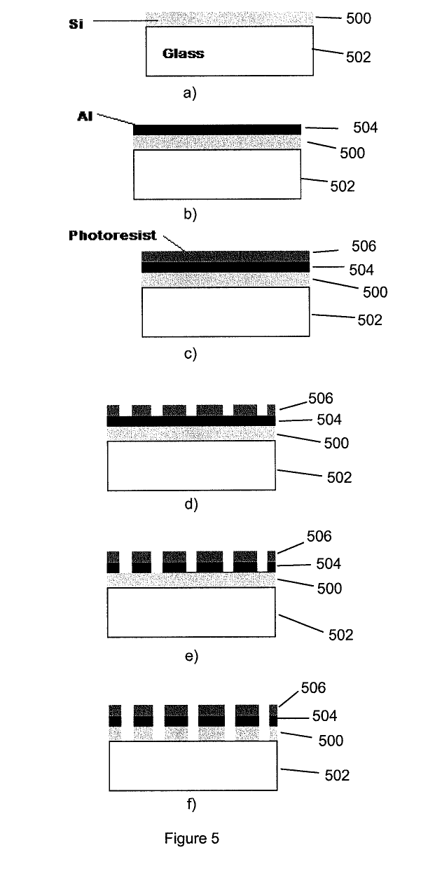

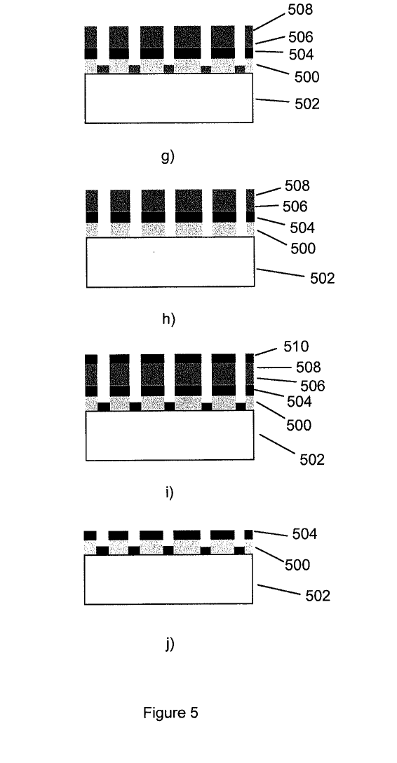

FIGS. 5a to j show schematic cross-sectional views illustrating one example manufacturing technique for fabricating an interdigitated poly-Si thin-film solar cell on a glass sheet. It will be appreciated by a person skilled in the art that different fabrication methods/techniques may be used for fabricating interdigitated solar cells, and the present invention is not limited to the fabrication method as described in FIGS. 5a to j.

Turning initially to FIG. 5a, a silicon layer (p⁺p⁻n⁺) 500 is deposited onto a glass substrate 502 for forming the basic cell structure. As shown in FIG. 5b, a metal layer 504, here aluminium, is evaporated over the silicon layer 500. Next, a photoresist 506 is deposited on top of the metal layer 504, as shown in FIG. 5c.

A shadow mask (not shown) is used to expose a metallization pattern onto the photoresist 506, which is subsequently developed to create an etching mask from the photoresist layer 506.

As shown in FIG. 5e, an etch is then performed to remove the exposed metal layer 504, in this example a phosphoric etch to remove the exposed Al layer 504. Subsequently, another etch is performed to remove the silicon down to the exposed surface of the glass substrate 502, in this example using a plasma etch, as shown in FIG. 5f.

As shown in FIG. 5g, a second photoresist layer 508 is then deposited over the entire structure, in this example using a spinning deposition process. The photoresist 508 is then exposed from the glass 202 side and developed.

As shown in FIG. 5i, a second metallization is then performed, in this example an aluminium evaporation, resulting in formation of an additional top metallization 510 and the glass-side electrode 512 on the glass substrate 502. The photoresist 506 and 508, and thus the aluminium top layer 510, is removed via lift-off, as shown in FIG. 5j. In this way, the glass-side electrode 512 as well as the air-side electrode 514 of the solar cells have been formed in an interdigitated way.

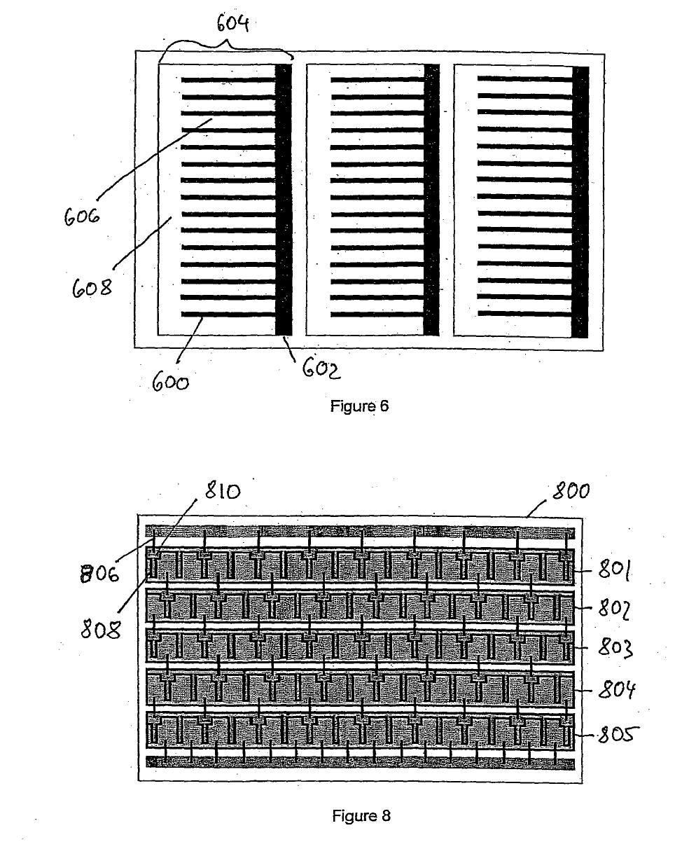

FIG. 6 shows a top (air-side) view of the structure after the step shown in FIG. 5j. More particular, in this example the glass-side electrode consists of glass-side fingers e.g. 600, as well as a glass-side busbar 602, for each of the cells e.g. 604. Likewise, the air-side electrode consists of air-side fingers e.g. 606 and an air-side busbar 608, for each of the cells e.g. 604.

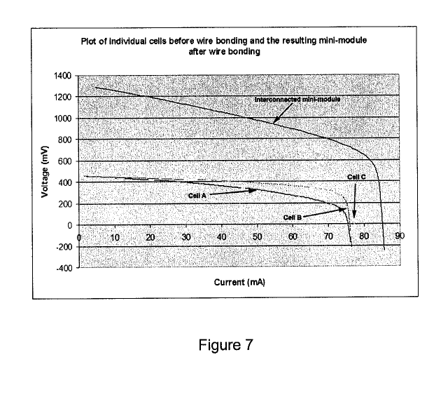

To investigate the practical application of wire-bonding to interconnect interdigitated solar cells, three poly-Si thin-film solar cells were individually measured prior to being interconnected via wire-bonding. The cells were then connected by a total of 14 wire-bonds per emitter/air-side busbar pair (compare embodiment shown in FIG. 2). The wire to form the bonds was aluminium wire (1% Si) with a diameter of 25 μm in the example cells. Current-voltage (I-V) measurements before and after interconnection are given in Table 1 and FIG. 7. All wirebond experiments described were conducted with a manual wedge wirebonder (model 4523) from the company K&S (Kulicke & Soffa).

From the Table 1 it can be seen that there are no major loss mechanisms present when the cells are interconnected via wire-bonding. The sum of the open-circuit voltages of cells A to C is 1369 mV, only ˜4% higher than the open-circuit voltage of the mini-module. Additionally, an increase of ˜10% in current can also be observed when forming the mini-module. The results from this first test run of wire-bonded interdigitated poly-Si solar cells illustrate the technical potential of this novel PV cell interconnection method.

TABLE 1
I-V results from the three solar cells before wire-
bond interconnection, and the resulting mini-module
after wire-bond interconnection according to the
embodiment described with reference to FIG. 2.
All measurements were performed using aperture
masks to define the illuminated device area.

| | | | | Interconnected |
|---|---|---|---|---|
| | Cell A | Cell B | Cell C | mini-module |
| V_{oc} (mV) | 459.5 | 457.5 | 452.1 | 1310.5 |
| I_{sc} (mA) | 75.6 | 76.1 | 77.4 | 85.0 |
| Efficiency | 3.8% | 5.1% | 5.1% | 4.2% |

FIG. 7 shows a plot of I-V curves measured for the three individual solar cells (A, B and C), and the resulting mini-module after interconnection using wire-bonding.

In another investigation, four poly-Si thin film solar cells were series connected via wire bonding and external leads were wire bonded to the first and last cells whereby the external leads consisting of tape with conductive surface and insulating bottom surface and placed onto the surface of the first respective last cell (compare embodiment shown in FIG. 4). Finally, the mini module was encapsulated by white paint.

From the Table 2 it can be seen that the combination of wire bonding and the application of conductive tape onto the surface of the cells yield a mini-module with enhanced performance compared to the individual cells.

TABLE 2
I-V results from four solar cells before wire-bond
interconnection, and the resulting mini-module
after wire-bond cell interconnection, wire-bond connection
of conductive tape to the first and last cell in the string
according to the embodiment described with reference
to FIG. 4, and encapsulation by white paint. All
measurements were performed using aperture masks
to define the illuminated device area.

| | | | | | Interconnected |
|---|---|---|---|---|---|
| | Cell A | Cell B | Cell C | Cell D | module |
| Voc (mV) | 430.8 | 433.3 | 433.3 | 431.7 | 1704.4 |
| Isc (mA) | 79.4 | 78.5 | 77.5 | 77.9 | 84.1 |
| FF (%) | 63.4 | 64.0 | 64.1 | 62.7 | 69.2 |
| Eff (%) | 4.9 | 5.0 | 4.9 | 4.8 | 5.6 |

PV modules preferably have long-term stability (>20 years) in the field. Therefore, the stability of the PV module fabrication method in example embodiments was also examined.

Initial stability testing indicated that there are no major concerns over the stability of both the wire bond interconnects and the poly-Si solar cells themselves. The testing involved repeated cycles of cooling in a freezer to −20° C. and then heating to approx. +40° C. in air, each for at least 20 minutes. As a result, water condensed on the surface each time the mini-module was taken out of the freezer due to the humidity of the air. The PV efficiency was tested at the conclusion of each cycle and was found to be stable.

Methods of encapsulation of the wire-bonded solar cells in different embodiments were also investigated. By applying a small number of coats of white paint over the real (air-side) surface of the interconnected poly-Si solar cells, it was found that this sufficiently planarized and encapsulated the surface and had no adverse effect on the wire bonds. Indeed, an increase in the performance was observed in some examples and is believed to be due to an increase in the internal reflectivity of the coated cells.

Five of the temperature cycles described above were performed on an encapsulated mini-module, the resulting efficiencies indicating no loss in performance due to this method of encapsulation. This example method of encapsulation thus provides a simple way to ensure the wire bonds are kept in place and are protected from breakage and corrosion due to the environment, handling and other factors.

In another embodiment, a wire bonding technique incorporates a glass-side or emitter ‘microbusbar’ of similar width to that of the emitter fingers. A wire bond connects a certain percentage of the emitter fingers directly to the air-side busbar of the neighbouring cell. In such an embodiment, one optimisation compromise consists of balancing the emitter shadow loss due to the minimum areas required for the wire bond (very small due to the small area of the contact pad needed), and the resistance loss across the microbusbar (also very small due to the number of wire bonds). An optimal wire-bond to emitter finger ratio may then be determined, which is not necessarily 1:1 (for example, a wire-bond to emitter finger ratio of 1:2 is shown in FIG. 7 below). The resistance loss can be calculated in a similar way as described above with reference to equation (1). The optimal cell dimensions can also need to be considered. It is expected that the dimensions will primarily depend on the minimum emitter finger width that can be developed, as well as the sheet resistances of the relevant metal contacts and semiconductor layers.

FIG. 8 shows a schematic air-side top view of a sample mini-module 800 containing five series-connected thin-film solar cells 801-805. In this design, there is one wire bond e.g. 806 for every two emitter fingers e.g. 808. In this example, each emitter finger e.g. 808 comprises a widened pad portion 810 for accommodating respective pad areas for the wire-bonding.

The methods of interconnecting two or more thin-film solar cells on a foreign supporting substrate according to the example embodiments comprise the step of wire-bonding an air-side electrode of one thin-film solar cell to a substrate-side electrode of an adjacent solar cell, such that said thin-film solar cells are connected in series.

In the described embodiments, wire (or ribbon) bonding provides a relatively cheap and reliable way to series interconnect interdigitated metallized thin-film solar cells. Compared to existing interconnection methods for interdigitated solar cells, increases in PV efficiency appear to be possible, primarily from a reduction in the power losses from both the shadowing and resistance of the emitter busbar. Preliminary stability tests performed on wire-bonded interdigitated poly-Si solar cells according to example embodiments the potential and stability of the process for an industrial production of thin-film PV modules.

The example embodiments described use ultrasonic wire-bonding to series-connect neighbouring interdigitated thin-film solar cells. Wire bonding as an interconnection technique can have a number of advantages, including:
Reliable technology.
Required equipment is readily available and relatively inexpensive.
The process of performing a wire-bond can take just seconds or less.
May be automated in a production line environment

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

For example, as an alternative to round wires, flattened wires or ribbons can be bonded in the same way as round wires. Ribbons can deliver advantages in certain applications such as high current photovoltaic devices, as the ribbons provide a greater cross-sectional area per unit area of busbar occupied by the bonds. This is due to the minimum pad area required between wire-bonds for adjacent bonds to take place.

Also, it will be appreciated that while glass substrates have been described in the example embodiments, the present invention is applicable to other supporting substrates including non-transparent substrates made from e.g. ceramic material.

1. A method of interconnecting two or more thin-film solar cells on a foreign supporting substrate, the method comprising the step of:
wire-bonding an air-side electrode of one thin-film solar cell to a substrate-side electrode of an adjacent solar cell, such that said thin-film solar cells are connected in series.

2. The method as claimed in claim 1, wherein the wire-bonding comprises using one or more of a group consisting of a round wire, a flattened wire, and a ribbon.

3. The method as claimed in claim 1, wherein the air-side electrode comprises an air-side busbar and a plurality of air-side finger electrodes connected to the air-side busbar, and the substrate-side electrode comprises a substrate-side busbar and a plurality of substrate-side finger electrodes connected to the substrate-side busbar.

4. The method as claimed in claim 3, comprising wire-bonding the air-side busbar of said one solar cell to the substrate-side busbar of said adjacent solar cell.

5. The method as claimed in claim 1, further comprising wire-bonding the substrate-side electrode of a first one of the series connected thin-film solar cells to a first external busbar, and wire-bonding the air-side electrode of a last one of the series connected thin-film solar cells to a second external busbar.

6. The method as claimed in claim 1, further comprising providing respective conductive tapes on a first one and a last one of the series of connected thin-film solar cells such that the conductive tapes are electrically insulated from surfaces of the first one and a last one of the series of connected thin-film solar cells, and wire-bonding the substrate-side electrode of the first one of the series connected thin-film solar cells and the air-side electrode of the last one of the series connected thin-film solar cells to the respective conductive tapes.

7. The method as claimed in claim 6, wherein the conductive tapes are adhered to the first one and the last one of the series connected thin-film solar cells via respective non-conductive adhesives.

8. The method as claimed in claim 1, further comprising encapsulating the wire-bonding formed connections.

9. The method as claimed in claim 8, wherein an entire air-side surface of the series connected thin-film solar cells is encapsulated.

10. A thin-film solar cell module comprising:
two or more thin-film solar cells; and
a wire-bonding-formed electrical connection between an air-side electrode of one thin-film solar cell to a substrate-side electrode of an adjacent solar cell, such that said thin-film solar cells are connected in series.

11. The solar cell module as claimed in claim 10, wherein the wire-bonding-formed connection comprises one or more of a group consisting of a round wire, a flattened wire, and a ribbon.

12. The solar cell module as claimed in claim 10, wherein the air-side electrode comprises an air-side busbar and a plurality of air-side finger electrodes connected to the air-side busbar, and the substrate-side electrode comprises a substrate-side busbar and a plurality of substrate-side electrodes connected to the substrate-side busbar.

13. The solar cell module as claimed in claim 12, wherein the wire-bonding-formed connection is between the air-side busbar of said one solar cell to the substrate-side busbar of said adjacent solar cell.

14. The solar cell module as claimed in claim 12, wherein the substrate-side busbar accommodates respective pad areas for the wire-bonding-formed connection.

15. The solar cell module as claimed in claim 12, wherein one or more of the substrate-side electrodes comprise a widened pad portion for accommodating respective pad areas for the wire-bonding-formed connection.

16. The solar cell module as claimed in claim 10, further comprising a wire-bonding-formed connection between the substrate-side electrode of a first one of the series connected thin-film solar cells to a first external busbar of the solar cell module, and a wire-bonding-formed connection between the air-side electrode of a last one of the series connected thin-film solar cells to a second external busbar of the solar cell module.

17. The solar cell module as claimed in claim 10, further comprising respective conductive tapes on a first one and a last one of the series of connected thin-film solar cells such that the conductive tapes are electrically insulated from surfaces of the first one and a last one of the series of connected thin-film solar cells, and wire-bonding formed connections of the substrate-side electrode of the first one of the series connected thin-film solar cells and the air-side electrode of the last one of the series connected thin-film solar cells to the respective conductive tapes.

18. The solar cell module as claimed in claim 17, wherein the conductive tapes are adhered to the first one and the last one of the series connected thin-film solar cells via respective non conductive adhesives.

19. The solar cell module as claimed in claim 10, further comprising an encapsulation for the wire-bonding formed connections.

20. The solar cell module as claimed in claim 19, wherein an entire air-side surface of the series connected thin-film solar cells is encapsulated.
